(19) United States
(12) Patent Application Publication
(10) Pub. No.: US 2026/0321576 A1
(43) Pub. Date: Oct. 15, 2026

(54) CELL QUALITY INSPECTION OF AQUEOUS BATTERY AND CELL BLOCK MANUFACTURING BASED ON SAME

(71) Applicant: Standard Energy Inc., Daejeon (KR)

(72) Inventors: Taeshik Yoon, Daejeon (KR); Dongyoung Lee, Daejeon (KR)

(21) Appl. No.: 19/688,404

(22) Filed: May 26, 2026

Related U.S. Application Data
(63) Continuation of application No. PCT/KR2024/096100, filed on Aug. 29, 2024.

(30) Foreign Application Priority Data
Nov. 27, 2023 (KR) 10-2023-0166370

(51) Int. Cl. H01M 4/04; G01R 31/385; G01R 31/389; H01M 10/42; H01M 10/44

(52) U.S. Cl. CPC H01M 4/0447; G01R 31/3865; G01R 31/389; H01M 10/425; H01M 10/441; H01M 2010/4271

(57) ABSTRACT

The present document relates to a quality inspection method for a cell of an aqueous battery, a device therefor, and a method of and a system for manufacturing a cell block on the basis of same. To this end, the method of manufacturing a cell block of an aqueous battery includes: stacking a plurality of cells each including a plurality of layers; injecting a liquid electrode into each of the cells stacked; performing primary quality control by applying power in a state where the cells are electrically connected; selecting cells having a quality equal to or greater than a predetermined reference according to a result of the primary quality control; and re-stacking the selected cells to manufacture the cell block.

### TECHNICAL FIELD

The following description relates to quality control of an aqueous battery, and more particularly, to a method and apparatus for performing quality inspection on an aqueous battery on a cell-by-cell basis, and a method for manufacturing a cell block based on the same.

### BACKGROUND

A secondary battery refers to a battery that is chargeable and dischargeable, unlike a primary battery that is not rechargeable. Such secondary batteries are used in various fields, including portable devices such as mobile phones and laptop computers, as well as electric vehicles and energy storage systems (ESSs).

Among these secondary batteries, the lithium secondary battery, which is currently most popular, has a larger capacity than the nickel-cadmium battery or the nickel-hydrogen battery and a high energy density per unit weight, and thus, is increasingly used.

The lithium secondary battery primarily uses a lithium-based oxide and a carbon material as positive and negative electrode active materials, respectively. The lithium secondary battery includes an electrode assembly in which a positive electrode plate and a negative electrode plate coated with the positive and negative electrode active materials, respectively, are disposed with a separator interposed therebetween, and a packaging material that hermetically houses the electrode assembly together with an electrolyte.

A secondary battery is generally manufactured by injecting a liquid electrolyte, that is, an electrolytic solution while an electrode assembly is housed in a battery case, and then sealing the battery case.

Such lithium secondary batteries may experience various types of defects due to various causes during the manufacturing process or use. In particular, some manufactured secondary batteries exhibit a voltage drop behavior exceeding a self-discharge rate, and this phenomenon is referred to as low voltage.

The low-voltage failure in such a secondary battery is frequently caused by metallic foreign substances located inside them. Specifically, when metallic foreign substances such as iron or copper exist on the positive electrode plate of the secondary battery, these metallic substances may grow into dendrites at a negative electrode. The dendrites may cause internal short circuits in the secondary battery, leading to failure or damage of the battery, or in a severe case, a fire.

Various technologies for inspecting a low-voltage failure in secondary batteries have been proposed.

For example, Korean Registered Patent No. 2,194,845 (registered on Dec. 17, 2020) proposes a method for rapidly detecting the aforementioned low-voltage failure in a secondary battery.

In addition, Korean Patent Publication No. 2021-0048327 (published on May 3, 2021) discloses a method for inspecting defects in an electrode for a secondary battery and a method for identifying and removing a defective electrode.

However, the quality inspection methods for a secondary battery described above only suggest measures for performing quality inspection mainly on a lithium secondary battery. They are unsuitable as quality inspection measures for an aqueous battery using liquid electrodes, as they do not take into account the specific characteristics of the aqueous battery.

### SUMMARY

To address the above problems, an aspect of the present disclosure proposes a method and apparatus for performing quality inspection on an aqueous battery on a cell-by-cell basis, and a method for manufacturing a cell block based on the same.

Further, a preferred embodiment of the present disclosure proposes a method for manufacturing a cell block by stacking cells such that multiple layers include an inspection electrode, removing defective cells based on cell quality control (QC), and then performing re-stacking cells with qualities equal to or greater than a predetermined quality, in consideration of the need for total inspection on each cell in an aqueous battery.

Further, a preferred embodiment of the present disclosure defines specific procedures for performing a cell QC and provides a criterion for verifying a cell quality in each procedure

Further, a preferred embodiment of the present disclosure proposes a quality control circuit device for efficiently performing a cell QC.

Further, a preferred embodiment of the present disclosure provides a procedure and a quality criterion for performing subsequent quality inspection on a re-stacked cell block basis after a cell QC.

It will be appreciated by persons skilled in the art that the objects that could be achieved with the present disclosure are not limited to what has been particularly described hereinabove and the above and other objects that the present disclosure could achieve will be more clearly understood from the following detailed description.

In an aspect of the present disclosure to achieve the above objects, a method of manufacturing a cell block of an aqueous battery using a liquid electrode is disclosed. The method includes: stacking a plurality of cells, each cell including a plurality of layers; injecting the liquid electrode into each of the cells; performing primary quality control by applying power to the cells that are electrically connected to each other; selecting one or more cells having a quality equal to or greater than a predetermined threshold according to a result of the primary quality control; and, and re-stacking the selected ones of the cells.

In another aspect of the present disclosure, a system for manufacturing a cell block based on cell quality inspection of an aqueous battery using a liquid electrode is disclosed. The system includes: a cell stacking unit configured to stack a plurality of cells, each cell including a plurality of layers; a liquid electrode injector configured to inject the liquid electrode into each of the cells stacked by the cell stacking unit; and a quality control circuit device configured to perform cell quality inspection by applying power to the cells that are electrically connected to each other. The cell stacking unit is further configured to select one or more cells of the cells having a quality equal to or greater than a predetermined threshold according to a result of the cell quality inspection, and to re-stack the selected ones of the cells.

In another aspect of the present disclosure, a method for performing cell quality inspection on an aqueous battery using a liquid electrode is disclosed. The method includes: performing first constant current (CC) charging to perform high-speed charging on a plurality of stacked cells with a current equal to or greater than a first threshold; performing second CC charging to perform low-speed charging with a current equal to or less than a second threshold after the first CC charging, applying a rest period for inducing self-discharge for a period of time equal to or greater than a third threshold after the second CC charging; and discharging the plurality of cells to a state of charge (SoC) equal to or less than a fourth threshold after the rest period.

In another aspect of the present disclosure, a quality control circuit device for performing cell quality inspection on an aqueous battery using a liquid electrode is disclosed. The device includes: a power supply in which a positive (+) electrode is connected to a first inspection electrode of a first cell among N cells connected in series, and a negative (−) electrode is connected to a second inspection electrode of an Nth cell; a relay configured to disconnect the power supply when applying a rest period; a timer connected to the power supply and the relay to perform control over time; and a battery management system (BMS) configured to control to perform voltage logging according to a time of the timer. The power supply is configured to change a current value during transition between first CC charging for performing high-speed charging on the N cells with a current equal to or greater than a first threshold and second CC charging for performing low-speed charging with a current equal to or less than a second threshold after the first CC charging.

In an embodiment of the present disclosure, the cell may be stacked by including an inspection electrode on an outer side of the plurality of layers.

Further, preferably, the liquid electrode may be injected after compressing the plurality of stacked cells.

Further, preferably, in the primary quality control, the plurality of cells may be connected in series, and a CC may be applied to the cells.

In an embodiment of the present disclosure, after performing the first CC charging, cells that do not satisfy a criterion of falling below a lower limit voltage, exceeding an upper limit voltage, or exceeding an open circuit voltage (OCV) upper limit among the plurality of cells, may be selected as cells having a quality equal to or greater than the predetermined threshold.

When a starting voltage of the rest period is 1.430V or less, or 1.480V or more, a corresponding cell may not be selected as a cell having a quality equal to or greater than the predetermined threshold.

More preferably, when a starting voltage of the rest period is 1.447V or less, or 1.460V or more, a corresponding may not be selected as a cell having a quality equal to or greater than the predetermined threshold.

Further, cells in which self-discharge exceeding an upper limit of voltage change does not occur during the rest period among the plurality of cells may be selected as cells having a quality equal to or greater than the predetermined threshold.

In the above embodiments, the first threshold may be determined in consideration of a limit of a quality control circuit device, and the second threshold may be determined in consideration of electrolyte stabilization.

Further, the third threshold may be set to a maximum time period in consideration of a manufacturing cycle of the aqueous battery, and the fourth threshold may be determined in consideration of disassembly into cells for re-stacking.

A preferred embodiment of the present disclosure may further include performing secondary quality control on the manufactured cell block, and the secondary quality control may be performed by repeatedly performing charging and discharging on the cell block a predetermined number of times.

Specifically, performing the secondary quality control may include performing cell stabilization including complete discharging of a cell undischarged in the primary quality control, measuring an internal resistance of the cell block by performing charging and discharging with a high current, inducing complete discharging by discharging with a low current, measuring a charge current amount by performing charging and discharging according to a standard cycle after the complete discharging, and completely charging the cell block.

The secondary quality control may be performed through a general-purpose charger/discharger.

In an embodiment of the present disclosure, re-stacking the cells may include, after performing the primary quality control, disassembling the plurality of cells on a cell basis, classifying types of the cells having a quality equal to or greater than the predetermined threshold according to at least one factor of charging performance or discharging performance, and performing re-stacking by grouping the cells according to the classified types.

In an embodiment of the present disclosure, the plurality of layers may include a separator, a pair of solid electrodes located at both outer ends of the separator, and a pair of current collectors located respectively on outer sides of the pair of solid electrodes, and the inspection electrode may be located on an outer side of each of the pair of current collectors.

Further, preferably, a frame having a predetermined thickness may be disposed on left and right sides of the pair of solid electrodes, and the predetermined thickness may be determined according to a degree to which the compressor compresses the plurality of cells.

Further, a horizontal area of the frame may be set such that a combined horizontal area of the frame and the solid electrode corresponds to a horizontal area of the current collector.

Further, the inspection electrode may have a thickness equal to or greater than a first thickness determined to prevent deformation of the current collectors due to the injection of the liquid electrode. Preferably, the inspection electrode may be made of 3T aluminum.

In the above embodiments, the aqueous battery may include a vanadium ion battery (VIB), and the cell block may correspond to, but is not limited to, a mono-block of the VIB. The above-described method is applicable to various aqueous batteries.

According to the embodiments of the present disclosure as described above, a method and apparatus for performing quality inspection on cells of an aqueous battery, and a method and system for manufacturing a cell block based on the same may be implemented efficiently.

Specifically, in a preferred embodiment of the present disclosure, considering the need for of total inspection of each cell in an aqueous battery, a defect-free cell block may be manufactured by stacking cells such that multiple layers include an inspection electrode, removing defective cells based on a cell QC, and then re-stacking cells having a quality equal to or greater than a predetermined threshold.

Further, in a preferred embodiment of the present disclosure, defective cells may be accurately excluded by defining specific procedures for performing a cell QC and providing criteria for verifying a cell quality in each procedure.

Further, in a preferred embodiment of the present disclosure, a quality control circuit device for efficiently performing a cell QC is proposed, allowing a procedure to be carried out in accordance with the characteristics of the cell QC.

Further, in a preferred embodiment of the present disclosure, a higher-level finished product may be provided by specifically presenting procedures and quality criteria for performing subsequent quality inspection on a re-stacked cell block after cell quality inspection.

The effects obtainable from the present disclosure are not limited to the effects described above, and other effects not described may be clearly understood by those skilled in the art to which the present disclosure belongs from the description below.

### BRIEF DESCRIPTION OF THE DRAWINGS

FIG. 1 is a diagram illustrating a vanadium redox flow battery (VRFB).

FIG. 2 is a diagram illustrating a vanadium ion battery (VIB) as an aqueous battery according to an embodiment of the present disclosure.

FIG. 3 is a diagram referred to for describing a reason why total inspection is required for quality control of a VIB according to an embodiment of the present disclosure.

FIG. 4 is a diagram illustrating a method for manufacturing a cell block of an aqueous battery using a liquid electrode according to an embodiment of the present disclosure.

FIG. 5 is a diagram illustrating a method for manufacturing a mono-block of a VIB using the embodiment of FIG. 4.

FIG. 6 is a diagram illustrating a specific method for performing primary quality control (QC) according to an embodiment of the present disclosure.

FIG. 7 is a diagram illustrating a quality control circuit device for performing cell quality inspection according to an embodiment of the present disclosure.

FIG. 8 is a diagram illustrating the concept of re-stacking cells that satisfy a QC criterion according to an embodiment of the present disclosure.

FIGS. 9 and 10 are diagrams illustrating the concept of performing secondary QC according to an embodiment of the present disclosure.

FIG. 11 is a diagram illustrating each step of the secondary QC according to an embodiment of the present disclosure.

### DETAILED DESCRIPTION

Embodiments of the present disclosure will be described in detail with reference to the accompanying drawings so that those skilled in the art may easily implement them. However, the present disclosure may be implemented in various different forms and is not limited to the embodiments described herein. In order to clearly describe the present disclosure, parts irrelevant to the description are omitted in the drawings, and similar reference numerals are assigned to similar parts throughout the specification.

Throughout the specification, when it is said that a certain part “includes” a certain component, this means that it may further include other components rather than excluding other components, unless otherwise specified.

In an aspect of the present disclosure, a method for performing quality inspection on cells of an aqueous battery is proposed as described above.

Aqueous batteries using liquid electrodes exist in various forms, including a vanadium redox flow battery (VRFB) and a vanadium ion battery (VIB) developed by the present applicant, as well as an aqueous zinc secondary battery using a water-based electrolyte.

Among the various aqueous batteries, the VRFB and VIB developed by the present applicant will be briefly described below.

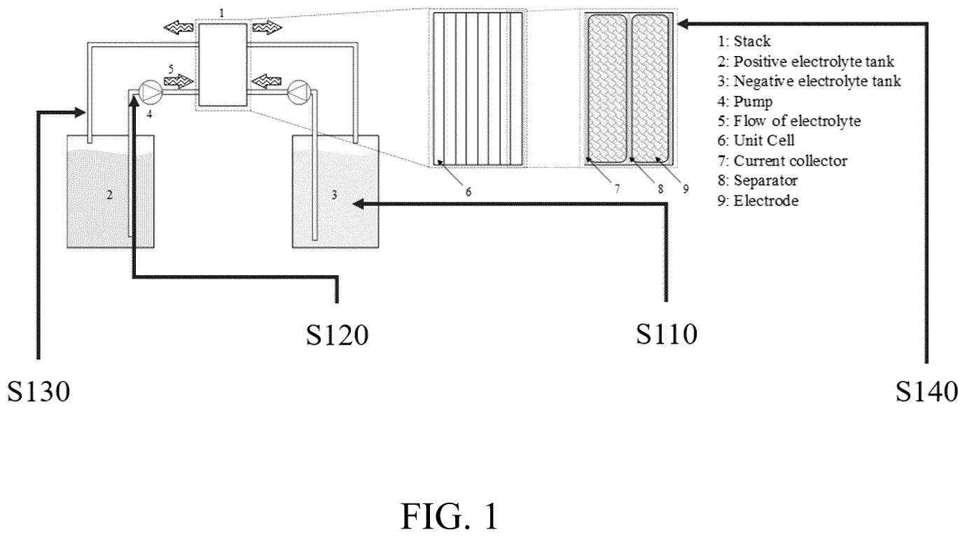

FIG. 1 is a diagram illustrating a VRFB.

As illustrated in FIG. 1, the VRFB may include a stack 1 in which vanadium-based battery cells are stacked, a positive electrolyte tank 2, a negative electrolyte tank 3, and a pump 4, as basic components.

The stack 1 has a structure in which unit cells 6 are stacked as illustrated on the right side, and each unit cell 6 may have a structure in which electrodes 9 are formed on both sides with a separator 8 interposed therebetween, and a current collector 7 is disposed to surround the electrodes 9.

A structure for generating current in this configuration will be described. First, a flow of electrolyte (S110) from the electrolyte tank 3 is generated (S120) using the pump 4, and this electrolyte flow moves (S140) to the battery stack 1 through a pipe (S130).

The VRFB may refer to a battery that generates current by returning the electrolyte to the tank after a vanadium redox reaction in the battery stack 1.

However, the above-described VRFB has problems such as energy consumption of the pump 4, ion imbalance within the tanks 2 and 3, occurrence of electrode flow path resistance due to a non-uniform electrolyte flow, and issues with plant-style piping, which leads to a decrease in energy efficiency.

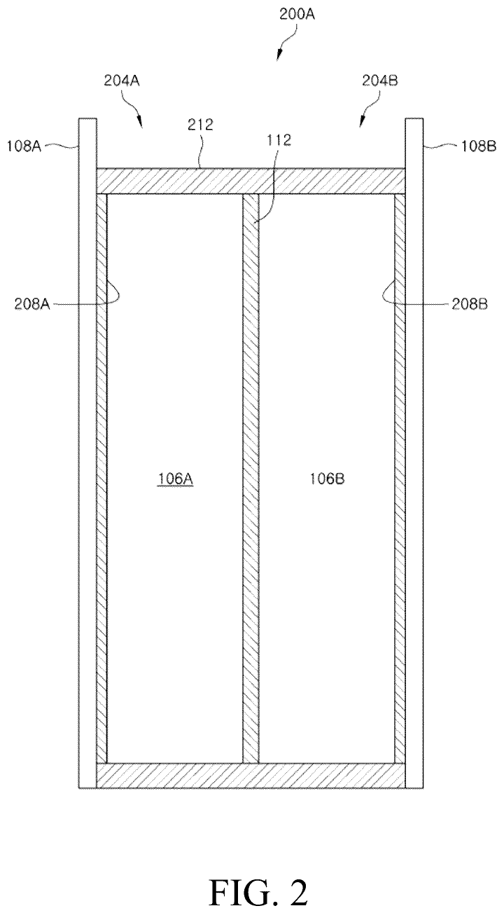

FIG. 2 is a diagram illustrating a VIB as an aqueous battery according to an embodiment of the present disclosure.

Referring to FIG. 2, the biggest structural difference from the VRFB described with reference to FIG. 1 is the absence of the pump 4. Instead, a VIB 200A of some embodiments is implemented such that ion relocation may occur within a positive electrolyte receiver 106A of a first half-cell 204A and a negative electrolyte receiver 106B of a second half-cell 204B, respectively. Various structural modifications are possible, and the reasons why ion relocation is possible include: the osmotic pressure difference between the two receivers 106A and 106B; a density change in both or one of the first and second electrolytes; diffusion or migration of both or one of the first and second electrolytes; first and second redox half-reactions; and/or expansion or contraction of both or one of the first and second electrolytes due to temperature.

The present inventors have recognized that sufficient stability, power supply, and energy output for the VIB may be provided as long as the cross-sectional thickness of the positive and negative electrolyte receivers 106A and 106B does not deviate from a specific value, for example, 20 cm, 15 cm, 10 cm, 5 cm, 2 cm, 1 cm, or a range defined by these values.

The VIB implemented in this manner may provide various technical and commercial advantages. For example, failures or reliability issues occurring in passages such as pipe/tube joints between a battery cell and a receiver (tank), and malfunction/misoperation of a pump used for electrolyte circulation may be minimized or eliminated, thereby reducing repair needs, safety issues, and operating costs related to the operation of the VIB 200A. Further, since there is no need to circulate electrolyte between a battery cell and a receiver (tank) using a pump, overall efficiency may be improved.

The present inventors have recognized that the use of the VIB 200A may increase power or an energy density by 2 to 50 times by eliminating the electrolyte circulation between the battery cell and the electrolyte tank required in the VRFB described above with reference to FIG. 2, depending on the size of the VIB 200A. As described above, power or an energy density refers to power or an energy density output relative to the total volume of an energy storage device. Therefore, in the VIB, power or an energy density refers to the ratio of the total capacity of the VIB and power or an energy output. Additionally, since equipment such as separate tanks, pumps, and circulation pipes required for an electrolyte circulation system is unnecessary, the space occupied by the energy storage device may be significantly reduced.

In addition, overall system complexity may be greatly reduced, thereby eliminating constraints on the commercial application of the VRFB. For example, unlike the VRFB of FIG. 1, the VIB 200A may be manufactured in a pack form similar to lithium-ion batteries, is suitable for an automated process and mass production, and obviates the need for cumbersome construction work required for installing the VRFB of FIG. 1.

The general operating principles and characteristics of a redox battery will be described below, taking a VIB based on vanadium-based redox pairs as an example. However, it should be understood that embodiments of the present disclosure are not limited thereto, and the principles described below are applicable to other types of redox batteries using different types of redox pairs.

As described above, liquid electrodes may be accommodated in the positive electrolyte receiver 106A and the negative electrolyte receiver 106B. A separator 112 (membrane) is disposed between these electrolyte receivers 106A and 106B, and it may be seen that protons move between separators 112 for electrical balance between the electrolytes, as described later.

The liquid electrodes contain ions undergoing redox (i.e., oxidation-reduction reactions). A first liquid electrode is an electrolyte in which an anode redox couple is dissolved. The anode redox couple may be implemented with a material including at least one of a transition metal such as titanium (Ti), vanadium (V), chromium (Cr), manganese (Mn), iron (Fe), cobalt (Co), or zinc (Zn), bromine (Br), or cesium (Cs) in the electrolytes of the present embodiments, a V2+/V3+ redox couple is dissolved, including vanadium (V).

The first liquid electrode may be an acidic aqueous solution, which is a solution that conducts current through ionization, and preferably includes sulfuric acid.

In the present embodiment, the first liquid electrode may be prepared by dissolving VOSO4 (vanadylsulfate), V2O5 (vanadium pentoxide), or other suitable materials in an H2SO4 aqueous solution.

The first liquid electrode undergoes a first half-reaction. The first half-reaction is expressed as Equation 1 below, where the right arrow (→) indicates a discharge reaction direction and the left arrow (←) indicates a charge reaction direction.

V²⁺←→V³⁺+e− Equation 1

In the above relationship, vanadium divalent ions are oxidized into vanadium trivalent ions during discharging, and vanadium trivalent ions are reduced into vanadium divalent ions during charging.

A second liquid electrode is an electrolyte in which a cathode redox couple is dissolved, and in the present embodiments, a V⁴⁺/V⁵⁺ redox couple may be present.

The second liquid electrode undergoes a second half-reaction. The second half-reaction is expressed as Equation 2 below, where the right arrow (→) indicates a discharge reaction direction and the left arrow (←) indicates a charge reaction direction.

V⁵⁺+e−←→V⁴⁺ Equation 2

Vanadium pentavalent ions are reduced to vanadium tetravalent ions during discharging, and vanadium tetravalent ions are oxidized to vanadium pentavalent ions during charging.

In the case of aqueous batteries including the VRFB and the VIB described above, it is preferable to manufacture a cell block by performing total inspection, unlike lithium-ion batteries.

This will be described in the context of the aforementioned VIB, by way of example.

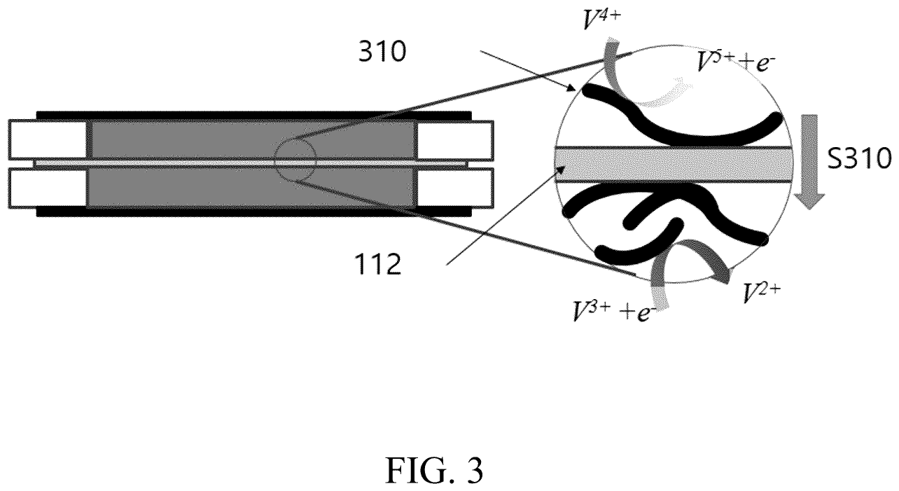

FIG. 3 is a diagram referred to for describing a reason for the need for total inspection for quality control of a VIB according to an embodiment of the present disclosure.

As illustrated in FIG. 3, carbon fibers 310 are randomly oriented between separators 112 in a VIB. Since the battery reaction of the VIB primarily occurs on the surfaces of the carbon fibers 310 in a solid electrode, the random orientation of the carbon fibers 310 may lead to significant variations in physical properties.

In this regard, it may be considered to perform quality control to the extent of excluding only a few outliers by measuring a surface density to grasp approximate physical properties. However, total inspection is preferable for quality control (QC) because the surface activity (hydrophilicity) varies depending on the degree of surface treatment, which leads to changes in internal fluid resistance.

Further, the necessity of total inspection in VIB QC may also be described in terms of utilizing liquid electrodes. In the VIB, since a relationship is established between a liquid electrode amount and a VIB capacity, inserting an accurate amount of liquid electrode into each cell may be the core of QC.

Additionally, because a liquid with a higher viscosity than water should be pushed into the narrow interior of a cell, there is a possibility of a capacity variation in each cell.

Due to these factors and other defects, a preferred embodiment of the present disclosure proposes performing grading through total inspection of an aqueous battery such as a VIB, and manufacturing a cell block (a mono-block in the case of a VIB) using only those cells with qualities equal to or greater than a predetermined quality threshold.

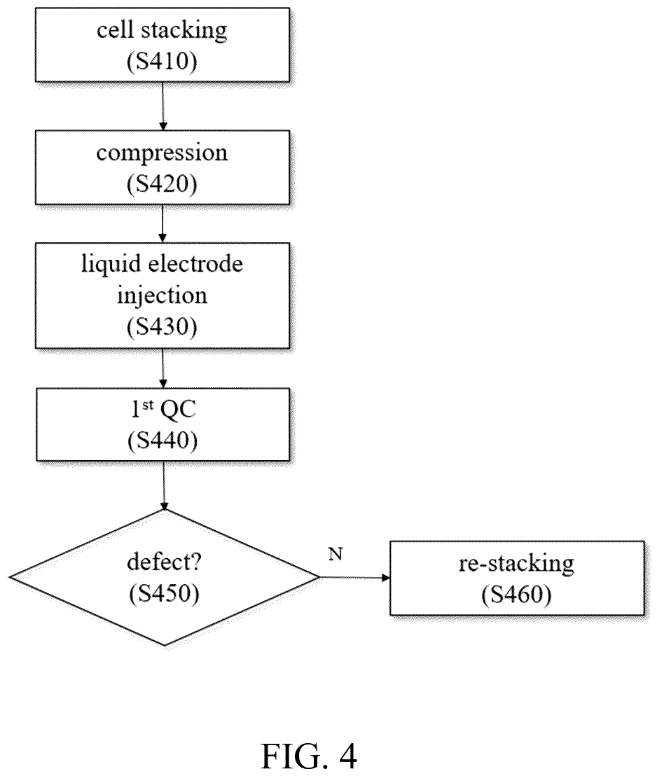

FIG. 4 is a diagram illustrating a method for manufacturing a cell block of an aqueous battery using a liquid electrode according to an embodiment of the present disclosure.

In the method according to the present embodiment, a cell including a plurality of layers may first be stacked (S410). When a system for manufacturing a cell block of an aqueous battery is configured, a cell stacking unit may be configured as a component for performing the cell stacking. This cell stacking unit may also be used for cell re-stacking, as described later.

The “layers” may correspond to the separator, the solid electrode, the current collector, and so on in the VRFB and the VIB described above with reference to FIGS. 1 and 2. In an embodiment of the present disclosure, it is proposed that stacking is performed by including an inspection electrode for each cell to facilitate primary QC, which will be described later.

Thereafter, a plurality of cells stacked with the cell are compressed (S420), and a liquid electrode may be injected into each of the compressed plurality of cells (S430). Although the compression S420 may be skipped depending on an applied cell type, the following description is given in the context of a battery type for which the compression S420 is performed, for the convenience of description.

When the system for manufacturing a cell block of an aqueous battery is configured, it is preferable to include an injector for injecting the liquid electrode.

It is necessary to prevent changes in the internal volumes of the layers due to the pressure of the liquid electrode injection or deformation of the current collector. In a preferred embodiment of the present disclosure, it is proposed that an inspection electrode is formed of a thick metal to perform this function. For example, the inspection electrode may be made of 3T aluminum, although a specific numerical value does not need to be limited thereto.

After the liquid electrode is injected (S430), it is proposed to perform primary QC by applying power while the plurality of cells are electrically connected (S440). The primary QC may be referred to as cell QC or cell-based QC, and needs to be distinguished from secondary QC (cell block QC) performed after the cell block is formed, which will be described later.

In an embodiment of the present disclosure, it is proposed that the primary QC is performed by connecting the plurality of cells in series and applying a constant current (CC).

When the primary QC is performed with a parallel connection/constant voltage configuration, it may be difficult to compare the cells because the current may vary between them. Specifically, in the parallel connection/constant voltage configuration, the presence of a defective cell or a cell into which the liquid electrode is not injected may affect the current values of other cells.

In contrast, applying a series connection/CC as in this embodiment has the advantage that a uniform current is applied across cells, making comparison easy. When a cell into which the liquid electrode is not injected or a defective cell exists, it is preferable to configure a circuit device described later to bypass that specific cell.

In this embodiment, it is proposed to manufacture the cell block by selecting one or more cells having qualities equal to or greater than a predetermined threshold according to a result of the primary QC (S450) and re-stacking the selected cells (S460). In other words, it is proposed to manufacture the cell block by performing the primary QC for each cell through total inspection, disassembling the stack into individual cells, and re-stacking only non-defective cells.

Further, in an embodiment of the present disclosure, it may be configured that the re-stacking S460 is performed by disassembling the plurality of cells after the primary QC S440, classifying cells that passed the primary QC S440 into types according to at least one factor of charging performance or discharging performance, and then grouping the cells based on these classified types.

The “re-stacking S460” performed in the embodiment of the present disclosure as described above may be seen as a distinguishing feature compared to embodiments where a VRFB or an LIB is applied.

For example, in the case of using a VRFB, once cell layers are stacked, it is difficult to disassemble them back into cells to perform re-stacking because the cells may be damaged during the disassembly.

In the case of using an LIB, there is a difference in that a single stacking process is performed using cells having qualities equal to or greater than a specific threshold, after QC, while separate stacking for performing cell QC (the primary QC) is not conducted.

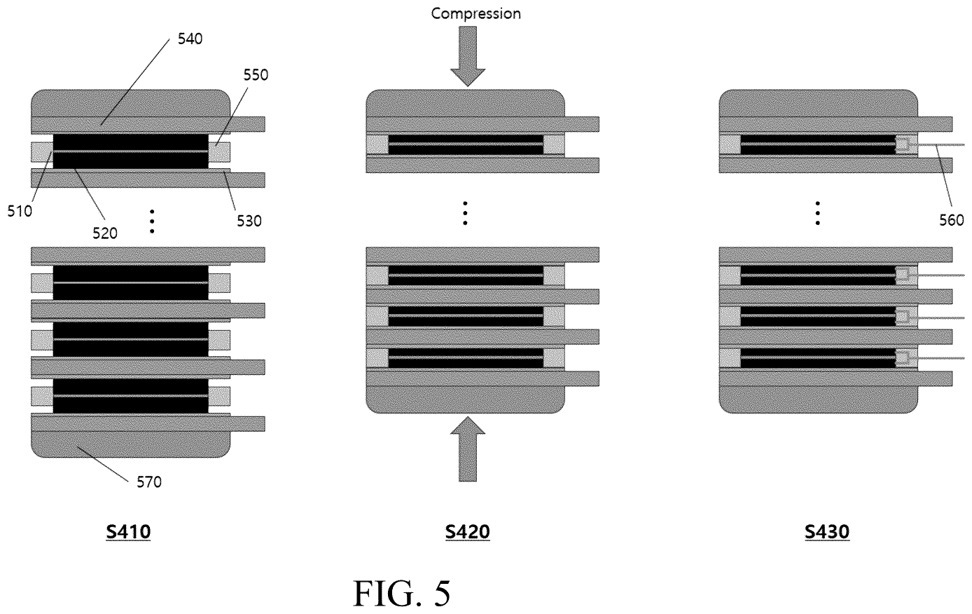

FIG. 5 is a diagram illustrating a method for manufacturing a VIB mono-block using the embodiment described above with reference to FIG. 4.

FIG. 5 illustrates cell stacking (S410) of a plurality of cells, according to the embodiment of FIG. 4 directed to a VIB. Specifically, a plurality of layers for each VIB cell may include a separator 510, a pair of solid electrodes 520 located at both outer ends of the separator 510, and a pair of current collectors 530 located respectively on outer sides of the pair of solid electrodes 520. An inspection electrode 540 may be located on an outer side of a current collector 530.

Additionally, a frame 550 having a predetermined thickness is disposed on the left and right sides of the solid electrode pair 520. The predetermined thickness may be determined according to a degree to which the plurality of cells are compressed in the subsequent step S420.

Further, the horizontal area of the frame 550 may be set such that the sum of the horizontal areas of the frame 550 and a solid electrode 520 correspond to the horizontal area of a current collector 530. This configuration may minimize the deformation of the current collectors 530 during compression in step S420 of FIG. 5.

In step S430 of FIG. 5, a liquid electrode 560 is injected into each electrode of the VIB. As described above, it is preferable that the inspection electrode 540 has a thickness equal to or greater than a first thickness determined to prevent deformation of the current collectors 530 caused by the injection of the liquid electrode 560. In an embodiment of the present disclosure, it is assumed that the inspection electrode is made of 3T aluminum.

To perform the cell stacking (S410), end plates 570 may be disposed on the top of the first cell and the bottom of the N^{th} cell among the N cells. It is preferable to configure the end plates 570 such that a compressive force may be uniformly transmitted throughout the layers during compression.

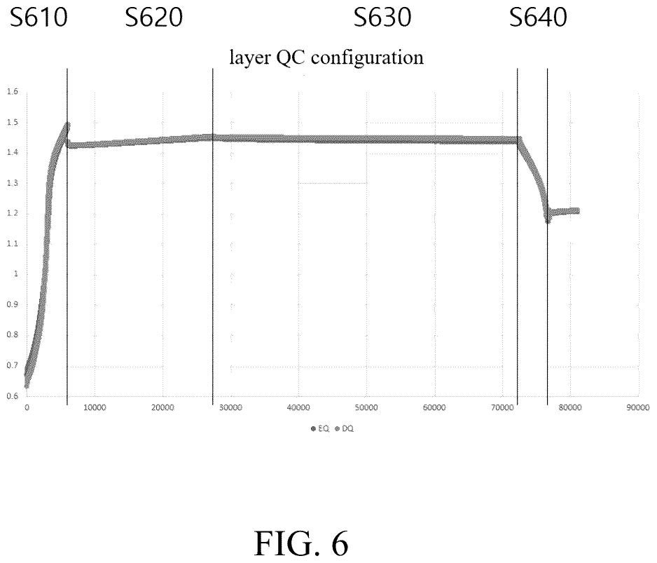

FIG. 6 is a diagram illustrating a specific method for performing primary QC according to an embodiment of the present disclosure.

As illustrated in FIG. 6, the primary QC cell QC may include performing first CC charging (S610) to perform high-speed charging on a plurality of cells with a current greater than or equal to a first threshold, performing second CC charging (S620) to perform low-speed charging with a current less than or equal to a second threshold after the first CC charging (S610), applying a rest period (S630) for inducing self-discharge for a period greater than or equal to a third standard after the second CC charging (S620), and discharging (S640) the plurality of cells to a state of charge (SoC) less than or equal to a fourth threshold after the rest period (S630). An additional rest period for transition/OCV measurement may be included between the aforementioned steps S610 to S640.

The meaning of each of steps S610 to S640 will be described in detail below. For better understanding, a specific example of applying the primary QC procedure to a VIB stacked with 32 cells is assumed, as illustrated in Table 1 below.

TABLE 1

| | Applied current (A) | Duration (s) | Reached voltage (V) |
|---|---|---|---|
| 1^{st} CC | 1.88 | 6000 | 1.46~1.53 (9 p.) |
| 2^{nd} CC | 0.075 | 21600 | ~1.46 |
| REST | 0 | 43200 | ΔV [symbol] [symbol] mV |
| Discharge | −2.2 | 5400 | ~1.2 |

In Table 1, the applied current (A) and duration(s) may be considered as fixed variables, while the reached voltage (V) refers to the measured value. The first CC charging (S610) described above may be seen as a process of separating the 3.5+ valent electrolyte into 4+ valency in each positive electrode and 3+ valency in the negative electrode. During this process, additional energy beyond general charging/discharging may be consumed.

Taking a specific example based on Table 1, the first threshold for a high-speed charging current in the first CC charging S610 may be 1.88 A (=0.85 C=2.2 A*0.85). However, the threshold is determined considering the limit of a device (a ‘quality control circuit device’ described later) used for high-speed charging. When the performance of the device allows, a higher current up to 1 C may be used.

As an example in Table 1, an embodiment of the present disclosure proposes continuing the first CC charging for up to 6000 seconds. Due to the charging for 6000 seconds, a charging current amount at this time may correspond to 3.13 Ah, and an additional 0.45 Ah may be charged later in the second CC charging step S620.

In the case of the VIB, since the cell capacity is 2.2 Ah, approximately 1.38 Ah may be seen as being used for electrolyte separation.

After the completion of the first CC charging S610, a cell state may be identified by measuring a reached voltage. The reached voltage may be affected by the internal resistance and energy capacity of the cell.

That is, a high internal cell resistance may be identified through a high charge-end voltage, and a high cell energy capacity may be identified through a low SOC at the end of charging, and also a low charge-end voltage.

Therefore, it is critical that the reached voltage falls within a specific range after the completion of the first CC charging S610. It is possible to measure the internal resistance of the cell by comparing the charge-end voltage with a voltage during a rest state between the first CC charging S610 and the second CC charging S620, which may be used for cause analysis if a problem occurs.

That is, in an embodiment of the present disclosure, it is proposed that among the plurality of cells, cells that do not satisfy a criterion of falling below a lower limit voltage, exceeding an upper limit voltage, or exceeding an OCV upper limit after performing the first CC charging S610 are selected as cells having qualities equal to or greater than the predetermined threshold. These criteria are illustrated in Table 2 below, based on a specific example applied to a VIB. The criteria in Table 2 are determined considering a specific yield based on statistical evidence. When the set yield is changed, different criteria may be applied.

TABLE 2

| | First type | | Second type | |
|---|---|---|---|---|
| | Lower limit | Upper limit | Lower limit | Upper limit |
| 1^{st} CC end | 1.46 V | 1.50 V | 1.48 V | 1.53 V |
| voltage | | | | |
| OCV drop | N/A | 12 mV | N/A | 12 mV |
| (voltage | | | | |
| difference | | | | |
| between start | | | | |
| and end of rest) | | | | |

As illustrated in Table 2, an embodiment of the present disclosure proposes that after the completion of the first CC charging S610, the criteria of falling below the lower limit voltage and exceeding the upper limit voltage are set differently depending on whether the cell is a first-type cell or a second-type cell. For example, it is preferable to set a first-type cell as a cell with good charging performance and a second-type cell as a cell with good discharging performance, so that re-stacking described later may be performed for each type of cell. However, the first type (charging performance) and the second type (discharging performance) are an exemplary type classification, and additional cell types may be defined and used for subsequent grouping. Further, the upper and lower limit voltages in Table 2 may be adjusted in consideration of a yield on a standard distribution. That is, when the upper limit voltage is increased and the lower limit voltage is decreased, the yield at the cell level increases, but the yield in the secondary QC of a cell block (mono-block) described later may decrease. Therefore, a preferred embodiment of the present disclosure proposes increasing the yield at the cell block level by reducing an individual cell-level yield and decreasing the deviation of each cell.

The meaning of each of the aforementioned inspection criteria may be described as follows.

First, when the voltage at the end of the first CC charging S610 falls below the lower limit, it may be viewed as a case where SOC deficiency occurs because the capacity increases due to over-injection of the electrolyte while the applied power remains the same, and also as a case showing an excessive self-discharge rate due to a low internal resistance.

In contrast, when the voltage at the end of the first CC charging S610 exceeds the upper limit, it may be viewed as a case where SOC excess (overcharge) occurs because the capacity decreases due to under-injection of the electrolyte while the applied power remains the same, and also as a case where electrochemical reaction efficiency within the cell is low due to a high internal resistance.

Additionally, when an OCV drop exceeds the upper limit, it may correspond to a case showing a high self-discharge rate due to poor separator bonding, a defective separator, or electrolyte crossover.

Since the preceding first CC charging S610 is high-speed charging, there is a possibility that an ion imbalance occurred in the electrolyte. Specifically, since the first CC charging S610 is high-speed charging performed while the electrolyte is not yet fully separated, it is preferable to perform electrolyte stabilization during the second CC charging S620.

Electrolyte stabilization may be achieved through methods such as maintaining a constant potential difference (constant voltage (CV) charging) and ultra-low speed charging/discharging (CC charging/discharging).

The key point of this step is a process of waiting for ions to become uniform over time. While this may be viewed as a process similar to the formation process of an LIB, it differs in that the duration is significantly shorter, 6 hours, as illustrated in Table 1.

In this embodiment, since the primary QC is conducted with 32 cells connected in series, applying a CV may cause an overload on some normal cells depending on the presence of defective cells. Moreover, as illustrated in FIG. 6, since the SOC is already sufficiently high, stabilization through additional ultra-low speed discharging may be inefficient.

Therefore, a preferred embodiment of the present disclosure proposes achieving stabilization by configuring the second CC charging S620 as an ultra-low speed CC charging. Specifically, it is proposed that the second threshold is determined in consideration of electrolyte stabilization as described above, and 0.034 C is applied to a VIB stacked with 32 cells as in Table 1. This may allow for resolving ion imbalance and seeking additional separation of an unseparated electrolyte. Since this results in a high SoC, it facilitates the verification of self-discharge during the subsequent rest period S630. However, the aforementioned values are exemplary and may be determined differently based on the equipment, time, and statistics applied.

Subsequently, a defective cell may be detected through the voltage of each cell at the start of the rest period S630.

A voltage range at the start of the rest period S630 may be set as follows.

TABLE 3

| | REST lower limit | REST upper limit |
|---|---|---|
| | defect voltage | defect voltage |
| Embodiment 1 | 1.430 V or less | 1.480 V or more |
| Embodiment 2 | 1.447 V or less | 1.460 V or more |
| Reason for defect | CE degradation, high capacity | Low capacity |

Specifically, while embodiment 1 presents a wider range than embodiment 2 in Table 3, and embodiment 2 may be used as the most optimal reference, these ranges are not necessarily limited to embodiment 1 and embodiment 2 because they may vary depending on battery characteristics (e.g., capacity Ah as well as charging/discharging conditions (e.g., the charging currents of the first CC and/or second CC). As illustrated in Table 1, when the starting voltage of the rest period S630 is equal to or lower than a threshold voltage, there are issues with CE degradation and/or a high cell capacity. When the starting voltage of the rest period S630 is equal to or higher than the threshold voltage, there may be an issue with a low cell capacity.

The rest period S630 may be viewed as a period for observing the self-discharge characteristics of the stacked cells through a long-duration rest.

In Table 1, which assumes a VIB stacked with 32 cells, the duration is assumed to be 12 hours (the third threshold). The third threshold may be set to a maximized time period in consideration of an aqueous battery manufacturing cycle. The example in Table 1 indicates that the maximum time period is 12 hours based on a VIB manufacturing cycle. In other words, a longer time period corresponding to the third threshold is more advantageous because self-discharge characteristics become more evident over a longer observation period.

A high self-discharge case usually corresponds to a low CE and a high voltage efficiency. Since self-discharge is affected by the state of the separator (membrane), it may be inferred that (high membrane permeability)==(electrolyte crossover)==(low CE). Conversely, it may also be inferred that (high membrane permeability) ==(easy ion migration)==(high voltage efficiency).

In a preferred embodiment of the present disclosure, a CE of 99.5% or higher may be targeted, and QC may be performed by setting an upper limit for a voltage change during the rest period S630. That is, among the plurality of cells, those that do not exhibit self-discharge, exceeding the upper limit of voltage change during the rest period S630 may be selected as cells having qualities equal to or greater than the predetermined threshold.

In the above description, the discharging S640 may be viewed as a procedure performed to disassemble the stack into cells after discharging to a low SoC (e.g., 1.2V), because a high SoC is unstable in terms of pressure and operator safety. In particular, since the plurality of cells are disassembled and reassembled individually later, and the current collectors are directly exposed and then reassembled, careful handling is required (short circuits or the like).

Therefore, in the above embodiment, the fourth threshold, which is an SoC criterion for the discharging S640, may be determined in consideration of cell-based disassembly for re-stacking, and in the example of Table 1, it may be shown as being determined as 1.2 V.

Further, in the case of a high SoC, the volume of the electrolyte increases slightly, and some gas may be additionally formed inside it. This may cause the cells to be damaged by instantaneous stress when the compressive force is released. Therefore, it is safe to discharge quickly before performing a subsequent task.

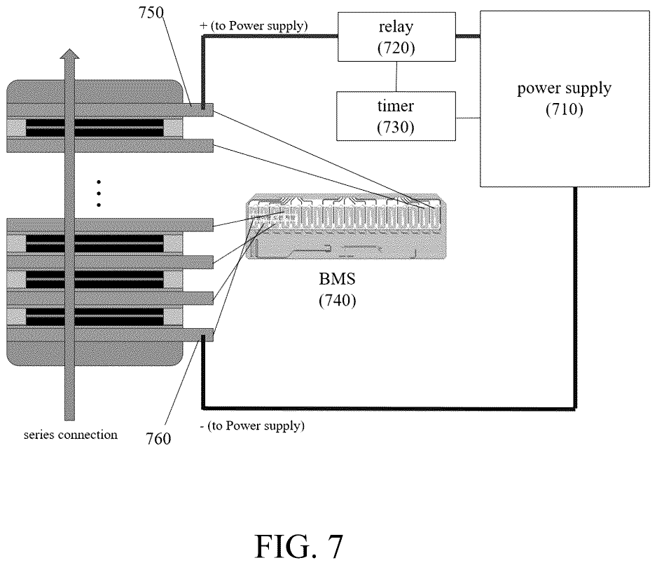

FIG. 7 is a diagram illustrating a quality control circuit device for performing cell quality inspection according to an embodiment of the present disclosure.

The circuit device illustrated in FIG. 7 may include a power supply 710 in which a positive (+) electrode is connected to a first inspection electrode 750 of a first cell, and a negative (−) electrode is connected to a second inspection electrode 760 of an N^{th} cell, among N cells connected in series. Additionally, the circuit device according to this embodiment may include a relay 720 configured to disconnect the power supply 710, when the rest period described with reference to FIG. 6 is applied.

Further, the circuit device according to this embodiment may include a timer 730 connected to the power supply 710 and the relay 720 to perform time-based control, and a BMS 740 that performs voltage logging according to a time of the timer 730.

In this case, the power supply 710 may be configured to change a current value during transition from first CC charging for performing high-speed charging with a current equal to or greater than a first threshold, to second CC charging for performing low-speed charging with a current equal to or less than a second threshold.

That is, the power supply 710 may be configured such that, according to a time of the timer 730, the first CC charging S610 described above with reference to FIG. 6, the second CC charging S620, the application of the rest period S630 through the relay 720, and the discharging S640 under the control of the BMS 740 are sequentially applied.

As illustrated in FIG. 7, the BMS 740 may include channels corresponding to the respective N cells. For example, when 32 cells are stacked, a 32-channel BMS 740 may be used. Additionally, the BMS 740 may serve to control discharging to be performed up to a specific voltage (e.g., 1.2V) after the application of the rest period.

Further, after the first CC charging is performed, the BMS 740 may assist in selecting cells that do not satisfy a criterion of falling below a lower limit voltage, exceeding an upper limit voltage, or exceeding an OCV upper limit as illustrated in Table 2 among the plurality of cells, as cells having qualities equal to or greater than a predetermined threshold.

Factors affecting the primary QC (cell QC) described above with reference to FIGS. 6 and 7 include the following factors.

First, a lower temperature may increase a cell voltage, and a higher temperature may decrease the cell voltage. Accordingly, in an embodiment of the present disclosure, it is proposed to set a temperature management threshold in a production line to 23±1 degrees.

Additionally, a lower resistance of the inspection electrode (e.g., 3T aluminum) (e.g., an electrode with a lower frequency of use and/or well-treated surface) may tend to decrease a voltage. Accordingly, in an embodiment of the present disclosure, it is proposed to perform the primary QC based on a specific resistance management threshold.

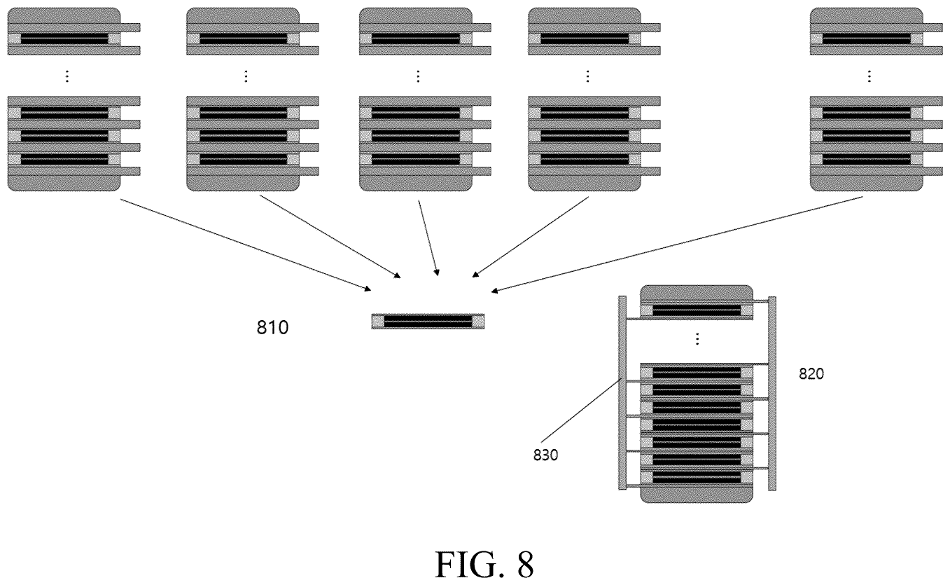

FIG. 8 is a diagram illustrating the concept of re-stacking cells that satisfy a QC criterion according to an embodiment of the present disclosure.

That is, while a plurality of cells are stacked as illustrated in FIG. 8, the above-described primary QC may be applied to select cells 810 exhibiting qualities equal to or greater than a predetermined threshold. In order to re-stack these cells 810, it may first be required to disassemble the stacked cells for inspection as described above.

In a cell block 820 re-stacked with the cells 810 that satisfy the QC criterion, each cell may be connected by a busbar 830. In the case of a VIB, this may correspond to a mono-block 820 of 1.2 to 1.5V and 110 A.

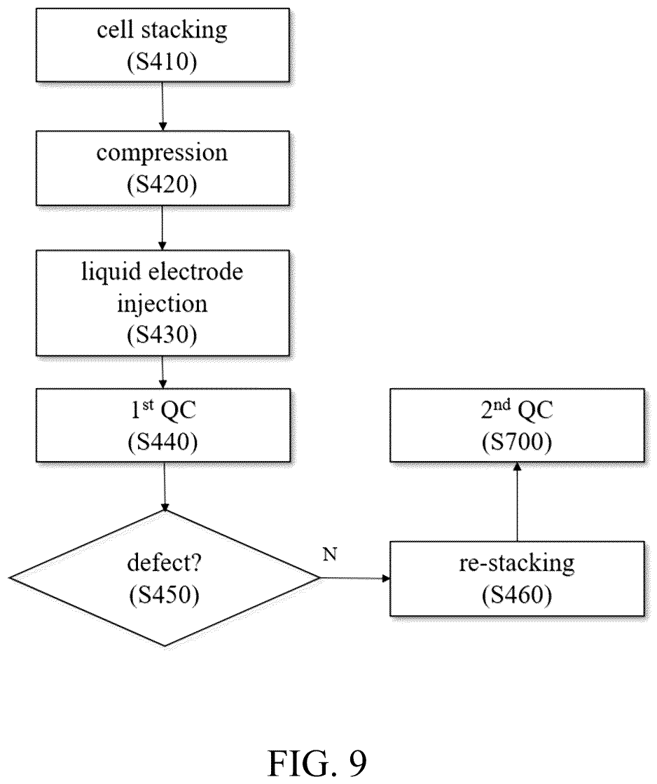

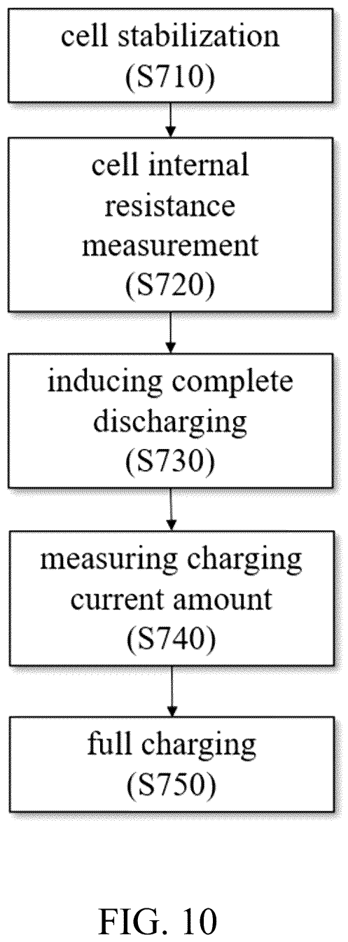

FIGS. 9 and 10 are diagrams illustrating the concept of performing secondary QC according to an embodiment of the present disclosure.

Referring to FIG. 9, the illustrated embodiment is identical to the embodiment described with reference to FIG. 4 in that cell stacking is performed (S410), stacked cells are compressed (S420), a liquid electrode is injected into the compressed cells (S430), primary QC corresponding to cell QC is performed (S440), cells that have passed the QC are selected (S450), and re-stacking is performed (S460) as described with reference to in FIG. 8.

FIG. 9 additionally illustrates the concept of performing secondary QC (the cell block QC S700) on re-stacked cells.

While a separate circuit device as described in relation to FIG. 7 is used for the primary QC, it is proposed to perform the secondary QC by repeatedly charging and discharging the re-stacked cell block a predetermined number of times using a general-purpose charger/discharger. Specifically, the secondary QC may proceed in the order of n cycles of CC charging/discharging->n cycles of CCCV charging/discharging->CCCV charging. CC charging/discharging involves rapid cycling, while CCCV charging/discharging may be performed according to group standards (e.g., for an VIB, SPS-C KBIA-10804-01-7563, enacted by the Korea Battery Industry Association on May 22, 2023).

Further, it is preferable to conclude the final step of the secondary QC (cell block QC) with a full charge. This serves the purpose of inspecting for leaks during storage of the cell block and observing self-discharge through a voltage measurement after long-term storage of the cell block.

In the secondary QC S700, a single product may be referred to as a single cell or a cell block, and in the case of a VIB, it may be referred to as a mono-block.

Specifically, referring to FIG. 10, the secondary QC S700 may include cell stabilization including completely discharging a cell undischarged in the primary QC (S710), measuring an internal resistance of a cell block by performing charging and discharging through a high current (S720), inducing complete discharging through low-current discharging (S730), measuring a charging current amount through charging and discharging according to a standard cycle after the complete discharging S730 (S740), and fully charging the cell block (S750).

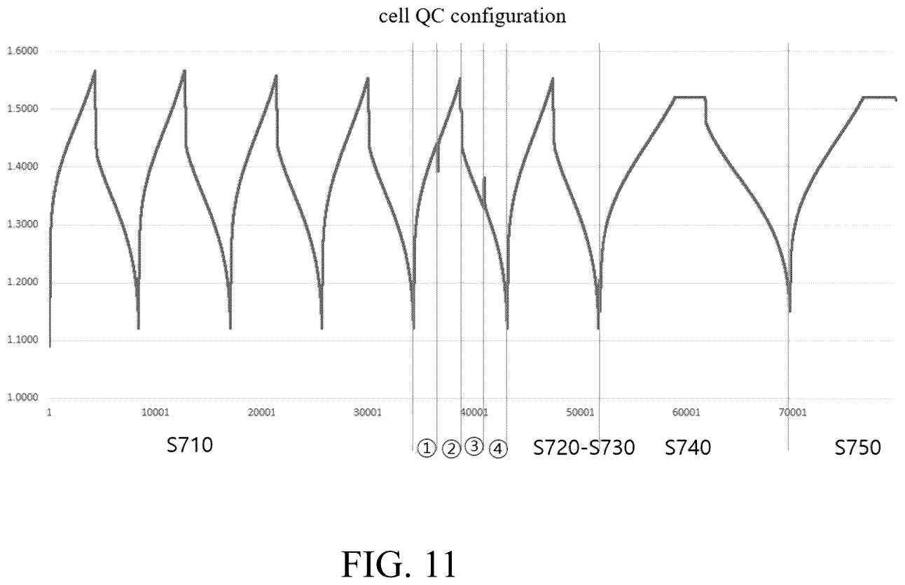

FIG. 11 is a diagram illustrating each step of the secondary QC according to an embodiment of the present disclosure.

As described above, the cell stabilization S710 is performed to completely discharge cells that remained undischarged during the primary QC. For this purpose, the cells are discharged until they reach 1.12V, followed by repeated CC-mode charging and discharging several times to achieve cell stabilization. FIG. 11 illustrates an example in which such charging and discharging are repeated for 4 cycles, but the number of repetitions is not necessarily limited thereto.

In the example of FIG. 11, a procedure labeled \textcircled{1} to \textcircled{4} is additionally performed between the cell stabilization S710 and the cell internal resistance measurement S720. These steps involve CC-mode charging (\textcircled{1} and \textcircled{2}) and CC-mode discharging (\textcircled{3} and \textcircled{4}). While not mandatory, they may be additionally performed for record-keeping and future cause analysis. Preferably, IR drop may be measured using a rest period between the procedures \textcircled{1} and \textcircled{2}, and IR rise may be measured using a rest period between the procedures \textcircled{3} and \textcircled{4}, which may then be used for analyzing subsequent measurement results.

Thereafter, in the cell block internal resistance measurement step S720, high-speed charging and discharging are performed in CC mode. During the high-speed charging, when a specific voltage (1.6V in the case of a VIB) is reached before a set time is completed, it may be treated as a defect. Additionally, in this step S720, a cell may be treated as a defect when a CE is less than 99% or 100% or more. Specifically, the CE less than 99% may be seen as a membrane abnormality, while the CE of 100% or more may be seen as an abnormality in the discharging of a previous cycle. This step S720 may make it possible to classify cells even when a chargeable capacity is low.

Next, the inducing of complete discharging through a low current S730 may be viewed as performing additional discharging at 0.5C defined as a standard cycle in the aforementioned VIB group standard. Discharging at a low current may allow for deeper discharging.

The measurement S740 of a charging current amount through charging and discharging according to the standard cycle may include CCCV-mode charging and CC-mode discharging. Considering that a charging current amount corresponds to an energy capacity, energy efficiency may also be measured in this step. Through this, it may be identified whether there is a CCCV capacity defect or a CC capacity defect.

Finally, the full charging S750 has the advantage of allowing for identifying whether leakage has occurred and a self-discharge rate during storage, as described above.

### ADDITIONAL EXAMPLES

### Example 1

A method for manufacturing a cell block of an aqueous battery using a liquid electrode, the method comprising:
stacking a cell including a plurality of layers;
injecting the liquid electrode into each of a plurality of cells stacked with the cell;
performing primary quality control by applying power in a state where the plurality of cells are electrically connected;
selecting cells having a quality equal to or greater than a predetermined threshold according to a result of the primary quality control; and
manufacturing the cell block by re-stacking the selected cells.

### Example 2

The method of Example 1, wherein in the primary quality control, the plurality of cells are connected in series, and a constant current (CC) is applied to the cells.

### Example 3

The method of Example 2, wherein performing the primary quality control includes:
performing first CC charging to perform high-speed charging on the plurality of cells with a current equal to or greater than a first threshold;
after the first CC charging, performing second CC charging to perform low-speed charging with a current equal to or less than a second threshold;
after the second CC charging, applying a rest period for inducing self-discharge for a period equal to or greater than a third threshold; and
discharging the plurality of cells to a state of charge (SoC) equal to or less than a fourth threshold after the rest period.

### Example 4

The method of Example 3, wherein when a starting voltage of the rest period is 1.430V or less, or 1.480V or more, a corresponding cell is not selected as a cell having a quality equal to or greater than the predetermined threshold.

### Example 5

The method of Example 3, wherein when a starting voltage of the rest period is 1.447V or less, or 1.460V or more, a corresponding is not selected as a cell having a quality equal to or greater than the predetermined threshold.

### Example 6

The method of Example 3, wherein after performing the first CC charging, cells that do not satisfy a criterion of falling below a lower limit voltage, exceeding an upper limit voltage, or exceeding an open circuit voltage (OCV) upper limit among the plurality of cells, are selected as cells having a quality equal to or greater than the predetermined threshold.

### Example 7

The method of Example 3, wherein cells in which self-discharge exceeding an upper limit of voltage change does not occur during the rest period among the plurality of cells are selected as cells having a quality equal to or greater than the predetermined threshold.

### Example 8

The method of Example 1, wherein re-stacking the cells include:
after performing the primary quality control, disassembling the plurality of cells on a cell basis;
classifying types of the cells having a quality equal to or greater than the predetermined threshold according to at least one factor of charging performance or discharging performance; and
performing re-stacking by grouping the cells according to the classified types.

### Example 9

The method of Example 3, wherein the fourth threshold is determined in consideration of disassembly into cells for the re-stacking.

### Example 10

The method of Example 3, wherein the primary quality control is performed through a quality control circuit including:
a power supply configured to change a current value during transition between the first CC charging and the second CC charging;
a relay configured to disconnect the power supply, when applying the rest period;
a timer connected to the power supply and the relay to perform control over time; and
a battery management system (BMS) configured to control to perform voltage logging according to a time of the timer and perform the discharging to a specific voltage after the application of the rest period.

### Example 11

The method of Example 1, further comprising performing secondary quality control on the manufactured cell block,
wherein the secondary quality control is performed by repeatedly performing charging and discharging on the cell block a predetermined number of times.

### Example 12

The method of Example 11, wherein performing the secondary quality control includes:
performing cell stabilization including complete discharging of a cell undischarged in the primary quality control;
measuring an internal resistance of the cell block by performing charging and discharging with a high current;
inducing complete discharging by discharging with a low current;
measuring a charge current amount by performing charging and discharging according to a standard cycle after the complete discharging; and
completely charging the cell block.

### Example 13

The method of Example 11, wherein the secondary quality control is performed through a general-purpose charger/discharger.

### Example 14

The method of Example 1, wherein the cell is stacked by including an inspection electrode on an outer side of the plurality of layers.

### Example 15

The method of Example 1, wherein the liquid electrode is injected after compressing the plurality of stacked cells.

### Example 16

A system for manufacturing a cell block based on cell quality inspection of an aqueous battery using a liquid electrode, the system comprising:
a cell stacking unit configured to stack a cell including a plurality of layers;
a liquid electrode injector configured to inject the liquid electrode into each of a plurality of cells stacked by the cell stacking unit; and
a quality control circuit device configured to perform the cell quality inspection by applying power in a state where the plurality of cells are electrically connected,
wherein the cell stacking unit is further configured to select cells having a quality equal to or greater than a predetermined threshold according to a result of the cell quality inspection of the quality control circuit device, and manufacture the cell block by re-stacking the selected cells.

### Example 17

The system of Example 16, wherein the cell stacking unit performs cell stacking by including an inspection electrode on an outer side of the plurality of layers.

### Example 18

The system of Example 17, wherein the plurality of layers include a separator, a pair of solid electrodes located at both outer ends of the separator, and a pair of current collectors located respectively on outer sides of the pair of solid electrodes, and
wherein the inspection electrode is located on an outer side of each of the pair of current collectors.

### Example 19

The system of Example 18, further comprising a compressor configured to compress the plurality of cells stacked by the cell stacking unit,
wherein the liquid electrode injector injects the liquid electrode into each of the cells compressed by the compressor.

### Example 20

The system of Example 19, wherein a frame having a predetermined thickness is disposed on left and right sides of the pair of solid electrodes, and
wherein the predetermined thickness is determined according to a degree to which the compressor compresses the plurality of cells.

### Example 21

The system of Example 20, wherein a horizontal area of the frame is set such that a combined horizontal area of the frame and the solid electrode corresponds to a horizontal area of the current collector.

### Example 22

The system of Example 18, wherein the inspection electrode has a thickness equal to or greater than a first thickness determined to prevent deformation of the current collectors due to the injection of the liquid electrode.

### Example 23

The system of Example 22, wherein the inspection electrode is made of 3T aluminum.

### Example 24

The system of Example 16, wherein the aqueous battery includes a vanadium ion battery (VIB), and
wherein the cell block corresponds to a mono-block of the VIB.

### Example 25

A method for performing cell quality inspection on an aqueous battery using a liquid electrode, the method comprising:
performing first constant current (CC) charging to perform high-speed charging on a plurality of stacked cells with a current equal to or greater than a first threshold;
after the first CC charging, performing second CC charging to perform low-speed charging with a current equal to or less than a second threshold;
after the second CC charging, applying a rest period for inducing self-discharge for a period equal to or greater than a third threshold; and
discharging the plurality of cells to a state of charge (SoC) equal to or less than a fourth threshold after the rest period.

### Example 26

The method of Example 25, wherein the first threshold is determined in consideration of a limit of a quality control circuit device, and
wherein the second threshold is determined in consideration of electrolyte stabilization.

### Example 27

The method of Example 25, wherein the third threshold is set to a maximum time period in consideration of a manufacturing cycle of the aqueous battery, and
wherein the fourth threshold is determined in consideration of disassembly into cells for re-stacking.

### Example 28

The method of Example 25, wherein when a starting voltage of the rest period is 1.430V or less, or 1.480V or more, a corresponding cell is not selected as a cell having a quality equal to or greater than a predetermined threshold.

### Example 29

The method of Example 25, wherein when a starting voltage of the rest period is 1.447V or less, or 1.460V or more, a corresponding cell is not selected as a cell having a quality equal to or greater than a predetermined threshold.

### Example 30

The method of Example 25, wherein after performing the first CC charging, cells that do not satisfy a criterion of falling below a lower limit voltage, exceeding an upper limit voltage, or exceeding an open circuit voltage (OCV) upper limit among the plurality of cells, are selected as cells having a quality equal to or greater than a predetermined threshold.

### Example 31

The method of Example 30, wherein the criteria of falling below the lower limit voltage and exceeding the upper limit voltage are set differently according to a first-type cell or a second-type cell.

### Example 32

A quality control circuit device for performing cell quality inspection on an aqueous battery using a liquid electrode, comprising:
a power supply in which a positive (+) electrode is connected to a first inspection electrode of a first cell among N cells connected in series, and a negative (−) electrode is connected to a second inspection electrode of an N^{th} cell;
a relay configured to disconnect the power supply when applying a rest period;
a timer connected to the power supply and the relay to perform control over time; and
a battery management system (BMS) configured to control to perform voltage logging according to a time of the timer;
wherein the power supply is configured to change a current value during transition between first constant current (CC) charging for performing high-speed charging on the N cells with a current equal to or greater than a first threshold and second CC charging for performing low-speed charging with a current equal to or less than a second threshold after the first CC charging.

### Example 33

The quality control circuit device of Example 32, wherein the BMS includes a channel corresponding to each of the N cells and is configured to control to perform discharging to a specific voltage after the application of the rest period.

### Example 34

The quality control circuit device of Example 33, wherein the power supply is configured such that the first CC charging, the second CC charging, the application of the rest period through the relay, and the discharging by the control of the BMS are sequentially applied according to a time of the timer.

### Example 35

The quality control circuit device of Example 34, wherein the BMS selects cells that do not satisfy a criterion of falling below a lower limit voltage, exceeding an upper limit voltage, or exceeding an OCV upper limit among the N cells after performing the first CC charging, as cells having a quality equal to or greater than a predetermined threshold.

### Example 36

The quality control circuit device of Example 35, wherein the criteria of falling below the lower limit voltage and exceeding the upper limit voltage are set differently according to a first-type cell or a second-type cell.

The above detailed description of the preferred embodiments of the present disclosure is provided to enable those skilled in the art to implement and practice the present disclosure. Although the description was made with reference to the preferred embodiments of the present disclosure, those skilled in the art will understand that various modifications and changes may be made to the present disclosure without departing from the scope of the present disclosure. For example, those skilled in the art may use the respective configurations described in the above embodiments in combination.

Therefore, the present disclosure is not intended to be limited to the embodiments shown herein but is to be accorded the widest scope consistent with the principles and novel features disclosed herein.

The method and apparatus for performing cell quality inspection on an aqueous battery, and the method and system for manufacturing a cell block based on the same according to the embodiments of the present disclosure as described above may be used for quality inspection and manufacturing of not only VRFBs and VIBs but also various other types of aqueous batteries.

What is claimed is:

1. A method of manufacturing a cell block of an aqueous battery using a liquid electrode, the method comprising:
stacking a plurality of cells, each cell including a plurality of layers;
injecting the liquid electrode into each of the cells;
performing primary quality control by applying power to the cells that are electrically connected to each other;
selecting one or more cells having a quality equal to or greater than a predetermined threshold according to a result of the primary quality control; and
re-stacking the selected ones of the cells.

2. The method of claim 1, wherein performing the primary quality control comprises:
electrically connecting the cells in series; and
applying a constant current (CC) to the cells.

3. The method of claim 2, wherein performing the primary quality control comprises:
performing first CC charging to perform high-speed charging on the cells with a current equal to or greater than a first threshold;
after the first CC charging, performing second CC charging to perform low-speed charging with a current equal to or less than a second threshold;
after the second CC charging, applying a rest period for inducing self-discharge for a period of time equal to or longer than a third threshold; and
after the rest period, discharging the cells to a state of charge (SoC) equal to or less than a fourth threshold.

4. The method of claim 3, wherein selecting the one or more cells comprises, after performing the first CC charging, selecting cells among the cells that do not satisfy at least one criterion of falling below a lower limit voltage, exceeding an upper limit voltage, or exceeding an open circuit voltage (OCV) upper limit as the one or more cells.

5. The method of claim 3, wherein selecting the one or more cells comprises, during the rest period, selecting cells that do not have self-discharge exceeding an upper limit as the one or more cells.

6. The method of claim 1, wherein re-stacking the selected ones of the cells comprises:
after performing the primary quality control, disassembling the cells on a cell basis;
classifying types of the selected ones of the cells according to at least one factor of charging performance or discharging performance; and
performing re-stacking by grouping the selected ones of the cells according to the types.

7. The method of claim 3, wherein the primary quality control is performed using a quality control circuit, the quality control circuit comprising:
a power supply configured to change a current value during transition between the first CC charging and the second CC charging;
a relay configured to disconnect the power supply when applying the rest period;
a timer connected to the power supply and the relay and configured to perform control over time; and
a battery management system (BMS) configured to perform voltage logging according to a time obtained by the timer and perform the discharging to a specific voltage after the rest period.

8. The method of claim 1, further comprising performing secondary quality control on the cell block by repeatedly performing charging and discharging on the cell block for a predetermined number of times.

9. The method of claim 8, wherein performing the secondary quality control comprises:
performing cell stabilization including complete discharging of a cell undischarged in the primary quality control;
measuring an internal resistance of the cell block by performing charging and discharging with a high current;
inducing complete discharging by discharging with a low current;
measuring a charge current amount by performing charging and discharging according to a standard cycle after the complete discharging; and
completely charging the cell block.

10. The method of claim 3, wherein the first threshold is determined in consideration of a limit of a quality control circuit device, and
wherein the second threshold is determined in consideration of electrolyte stabilization.

11. The method of claim 3, wherein the third threshold is set to a maximum time period in consideration of a manufacturing cycle of the aqueous battery, and
wherein the fourth threshold is determined in consideration of disassembly into cells for re-stacking.

12. A system for manufacturing a cell block of an aqueous battery using a liquid electrode, the system comprising:
a cell stacking unit configured to stack a plurality of cells, each cell including a plurality of layers;
a liquid electrode injector configured to inject the liquid electrode into each of the cells stacked by the cell stacking unit; and
a quality control circuit device configured to perform cell quality inspection by applying power to the cells that are electrically connected to each other,
wherein the cell stacking unit is further configured to select one or more cells of the cells having a quality equal to or greater than a predetermined threshold according to a result of the cell quality inspection, and to re-stack the selected ones of the cells.

13. The system of claim 12, wherein at least one cell of the cells comprises an inspection electrode on an outer side of the layers of the at least one cell, and the cell stacking unit is configured to perform cell stacking using the inspection electrode.

14. The system of claim 13, wherein the layers comprise a separator, a pair of solid electrodes located at both outer ends of the separator, and a pair of current collectors located respectively on outer sides of the pair of solid electrodes, and
wherein the inspection electrode is located on an outer side of each of the pair of current collectors.

15. The system of claim 14, further comprising a compressor configured to compress the cells stacked by the cell stacking unit,
wherein the liquid electrode injector is configured to inject the liquid electrode into each of the cells compressed by the compressor.

16. The system of claim 15, wherein a frame having a predetermined thickness is disposed on left and right sides of the pair of solid electrodes, and
wherein the predetermined thickness is determined according to a degree to which the compressor compresses the cells.

17. The system of claim 16, wherein a horizontal area of the frame is configured such that a combined horizontal area of the frame and a solid electrode of the pair of solid electrodes corresponds to a horizontal area of a current collector of the pair of current collectors.

18. The system of claim 14, wherein the inspection electrode has a thickness equal to or greater than a first thickness determined to prevent deformation of the current collectors due to the injection of the liquid electrode.

19. The system of claim 12, wherein the quality control circuit device comprises a battery management system (BMS) configured to control a performance of voltage logging according to a time obtained by a timer, and
wherein, after performing a first constant current (CC) charging, the BMS is further configured to select, among the cells, selected ones of the cells that do not satisfy at least one criterion of falling below a lower limit voltage, exceeding an upper limit voltage, or exceeding an OCV upper limit, as the selected ones of the cells.

20. The system of claim 19, wherein criteria for falling below the lower limit voltage and exceeding the upper limit voltage of a first-type cell are set differently from criteria for falling below the lower limit voltage and exceeding the upper limit voltage of a second-type cell.
